(19) United States
(12) Patent Application Publication
(10) Pub. No.: US 2025/0385663 A1
(43) Pub. Date: Dec. 18, 2025

(54) PHASE INTERPOLATOR

(71) Applicant: Intel Corporation, Santa Clara, CA (US)

(72) Inventors: Jieqiong Du, Los Angeles, CA (US); Yinghong Jiang, Folsom, CA (US); Mingming Xu, Phoenix, AZ (US); Vijayalakshmi Ramachandran, Chandler, AZ (US)

(21) Appl. No.: 18/744,273

(22) Filed: Jun. 14, 2024

(51) Int. Cl. H03K 5/135; H03D 7/14

(52) U.S. Cl. CPC H03K 5/135; H03D 7/1441

(57) ABSTRACT

Embodiments herein relate to a phase interpolator which includes a mixer having multiple legs or branches. Each leg includes a current path with p-type and n-type transistors in series. A bias generator provides a bias voltage for first p-type and n-type transistors in each leg. The bias voltage is also a function of an AC-coupled version of an input clock signal. Control voltage generators provide control voltages for second p-type and n-type transistors in each leg. The current in each leg is a function of the degree to which the transistors are conductive. Currents which are output from the different legs are combined at an input to a feedback circuit which may use a shunt resistor feedback path. Transistors in the bias generator and the control voltage generators may be replicas of the transistors in the legs.

### BACKGROUND

A phase interpolator is a circuit used in communication systems to adjust the phase of a signal. A phase interpolator typically provides an output clock signal having a phase which is formed from an interpolation of the phases of two or more input clock signals. It can be used in applications where precise phase alignment or phase shifting is required. However, various challenges are presented in designing a phase interpolator.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example circuit 100 which includes phase interpolators 120 and 140, in accordance with various embodiments.

FIG. 2A depicts example plots 200, 201 and 202 of the clock signals clk[1], clk[2] and clk[3], respectively, which are input to the phase interpolator (PI) 120 of FIG. 1, in accordance with various embodiments.

FIG. 2B depicts example plots 210 and 211 of clock signals output from the mixers 122 and 142, respectively, of FIG. 1, in accordance with various embodiments.

FIG. 2C depicts example plots 220 and 221 of clock signals at the output nodes 125 and 145, respectively, of the feedback circuits 124 and 144, respectively, of FIG. 1, in accordance with various embodiments.

FIG. 3 depicts an example phase interpolator 300 which include a bias generator 327, and an example implementation of the mixer 122 and feedback circuit 124 of FIG. 1, in accordance with various embodiments.

FIG. 4A depicts an example implementation of the first control voltage generator 400 of FIG. 3, in accordance with various embodiments.

FIG. 4B depicts an example implementation of the second control voltage generator 450 of FIG. 3, in accordance with various embodiments.

FIG. 5 depicts a circuit 500 which provides an example implementation of the mixer legs 310, 320 and 330 of FIG. 3 which receive signals clk[1], clk[2] and clk[3], respectively, in accordance with various embodiments.

FIG. 6A depicts a phase diagram consistent with the phase interpolator 300 of FIG. 3, in accordance with various embodiments.

FIG. 6B depicts a circuit 610 to provide in-phase (I) components of signals having phases consistent with FIG. 6A, in accordance with various embodiments.

FIG. 6C depicts a circuit 620 to provide quadrature (Q) components of signals having phases consistent with FIG. 6A, in accordance with various embodiments.

FIG. 7 depicts example plots of a differential nonlinearity (DNL) versus PI code for different process, voltage and temperature (PVT) corners consistent with the phase interpolator 300 of FIG. 3, in accordance with various embodiments.

FIG. 8A depicts a flowchart of a method for operating a PI consistent with the circuits of FIGS. 1-5, in accordance with various embodiments.

FIG. 8B depicts a flowchart of a method consistent with operation 803 of FIG. 8A, in accordance with various embodiments.

FIG. 9 illustrates an example of components that may be present in a computing system 950 for implementing the techniques (e.g., operations, processes, methods, and methodologies) described herein.

### DETAILED DESCRIPTION

As mentioned at the outset, various challenges are encountered in designing a phase interpolator.

Phase interpolators (PIs) are circuits uses to provide precision timing, e.g., in clock and data recovery (CDR) in high-speed input-output (HSIO) applications. A PI generates a desired clock phase for CDR by interpolating between two or more reference clocks. As data bandwidth increases and semiconductor technology scales, it is desirable for a PI to have properties including a linear transfer function with high-resolution to improve link margin, insensitivity to process, supply voltage and temperature (PVT) variations, compatibility with low-supply voltages, power-efficiency to meet a power budget, and low jitter and jitter amplification.

Other considerations include sensitivity to variations in the input/output common mode and the magnitude of the voltage swing of the PI. These considerations can require additional circuitry before and/or after the PI.

One approach to designing a PI involves current-mode logic (CML). However, this type of PI tends to be power-hungry, requiring a high supply voltage. In this approach, the interpolation of the phases is achieved by summation of different weighted inputs through tail currents. However, a disadvantage is the large static power consumption and voltage headroom requirement, which make it power-hungry and thus unsuitable for a low power supply process. Furthermore, it requires the input direct current (DC) common mode to be within a certain range to be functional. The output swing is also limited, and an amplifier may be required to amplify the output to the desired voltage swing, which further degrades the power-efficiency.

Another approach involves a Complementary Metal-Oxide-Semiconductor (CMOS) inverter, also referred to as a voltage-mode PI. While this approach is more power-saving than the CML approach, it is sensitive to PVT variations. Though more suitable for low power supply, low-power operation in advanced technology nodes, the linearity of the CMOS-inverter-based PI is sensitive to the input/output slope and to PVT variations. The linearity can be improved by reducing the input phase difference. However, this requires multiple clock phases, is expensive to implement, and slows down the slope of clock with resistor-capacitor (RC) filters. This in turn increases jitter and jitter amplification. To reduce PVT sensitivity, a current-starved inverter or a PVT-tracking low-dropout (LDO)-powered inverter-based PI can be used. However, with the above CMOS-based PI, a rail-to-rail input voltage swing is also required, which may not be available and requires additional circuitry for amplification, thereby degrading system power and jitter.

The solutions provided herein address the above and other issues. In one approach, a PI is provided which achieves compatibility with a low power supply, has good power-efficiency and is more robust to PVT variations than the CMOS-based PI. In an example implementation, the PI uses alternating current (AC)-coupled, separately biased inputs with p-type and n-type transistors, with a current-bias scheme to compensate for PVT variations. The proposed PI is also able to provide a very fine resolution with good linearity which is also important for overall link performance.

In an example implementation, the PI uses a modified CMOS-inverter-based mixer cell with AC-coupled inputs with separate bias voltages for p-type and n-type transistors, such as p-type and n-type metal-oxide-semiconductor field-effect transistors (MOSFETs). The PI provides a PVT-tracking bias with constant current and eliminates performance sensitivity to input common mode variations. The PI can include a mixer, a circuit to generate a bias voltages for the p-type and n-type transistors, and a feedback circuit after the mixer. For example, the feedback circuit can include a multi-stage inverter and a resistor in a feedback path. The feedback circuit, which is after the mixer, reduces the DC impedance and biases the circuit at high gain. This enables the PI to work with a low-to-medium voltage input swing while generating a rail-to-rail output swing. Moreover, by generating a phase control voltage through a current digital-to-analog converter (DAC) with a replica load of the mixer, a high resolution of the PI is achieved without impacting the bandwidth.

The solutions provide a number of advantages, including achieving a high phase resolution for receiver data sampling and Decision-Directed Feedforward Equalization (DDFE). In one approach, the solution can be used to enable Pulse Amplitude Modulation 4-level (PAM-4) in Peripheral Component Interconnect Express (PCIe) GEN6 with a power-optimized design under a low power supply of 0.75V. PCIe is a serial expansion bus standard for connecting a computer to one or more peripheral devices. Another example implementation is with next-generation Universal Serial Bus Type-C CIO80 PHY for optimized power consumption. The above advantages improve the HSIO link margin and power-efficiency.

These and other features will be further apparent in view of the following discussion.

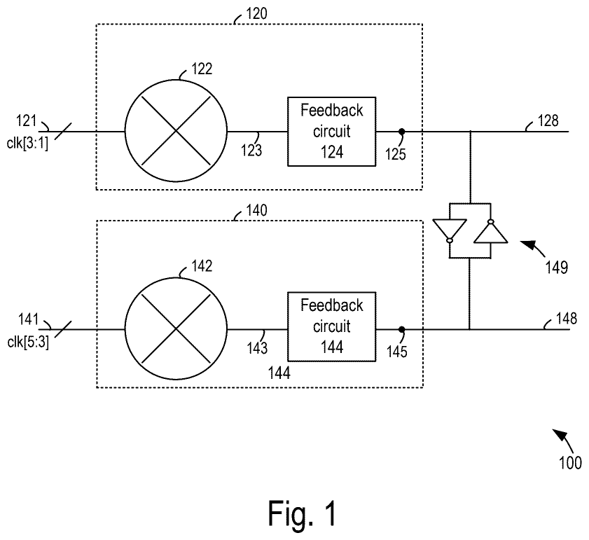

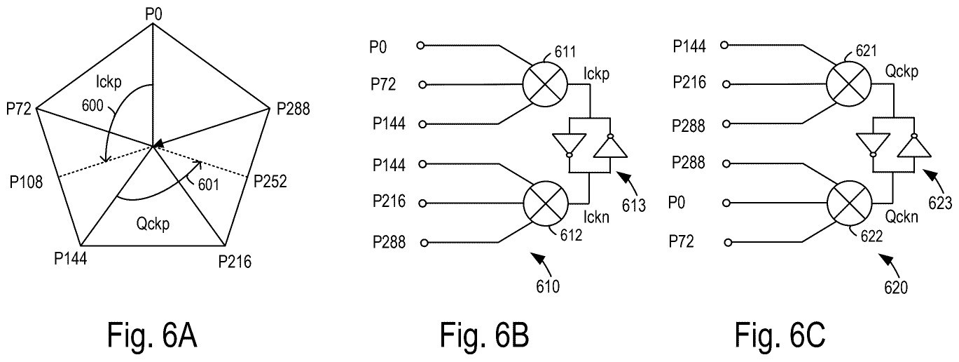

FIG. 1 depicts an example circuit 100 which includes phase interpolators 120 and 140, in accordance with various embodiments. A phase interpolator (PI) is a circuit used to generate an output clock signal with a phase that lies between the phases of two or more input clock signals. In this example, three clock signals are received by each PI. Specifically, clk[3:1], which represents first, second and third clock signals clk[1], clk[2] and clk[3], respectively, is received at an input 121 of the PI 120, and clk[5:3], which represents the same third clock signal clk[3] along with fourth and fifth clock signals clk[4] and clk[5], respectively, is received at an input 141 of the PI 140. The five different clock signals can be 72 degrees apart in phase to provide clk[1], clk[2], clk[3], clk[4] and clk[5] with phases of 0, 72, 144, 216 and 288, respectively, for examples. See also FIG. 6A. Other numbers of clocks and phase separations could be used as well.

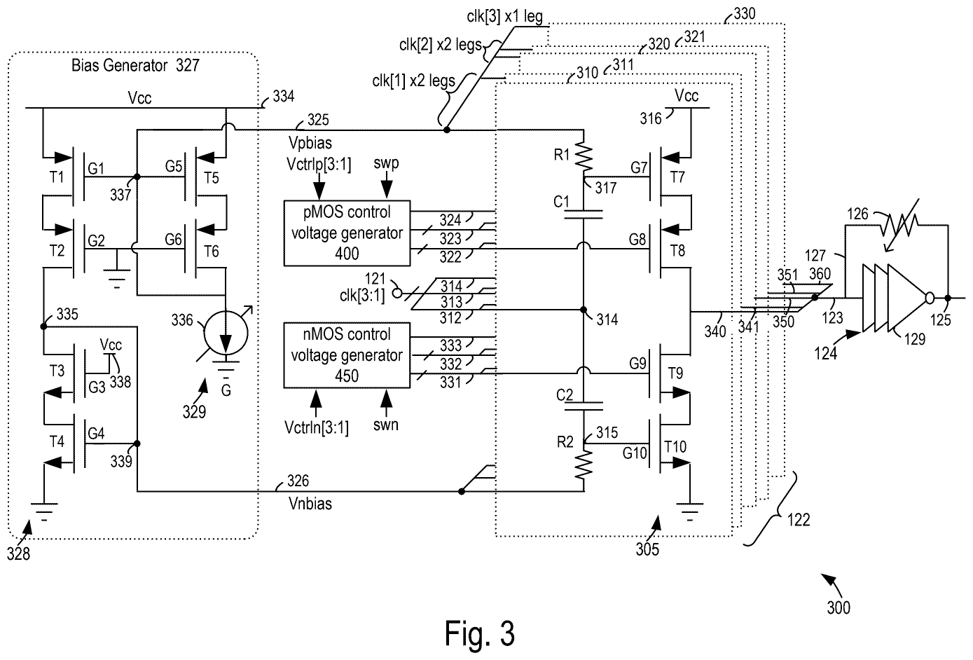

The PI 120 includes a mixer 122 which provides an output current at an output node 123 based on the input clocks, and bias voltages and control signals discussed further below. The output node 123 is common to the different legs of the mixer. The output currents from the legs result in a voltage at the node 123 that is input to a high-gain amplifier with shunt resistor feedback circuit 124. An example implementation of the feedback circuit 124 is provided in FIG. 3. An output node 125 of the feedback circuit 124 is a new clock signal with a same frequency as the input clock signals but with a phase which is obtained by interpolation. The new clock signal is coupled to an output path 128 of the PI and to an inverter pair 149 of back-to-back connected inverters.

Similarly, the PI 140 includes a mixer 142 which provides an output voltage at an output node 143 based on the input clocks, bias voltages and control signals. The output voltage is a new clock signal with a same frequency as the input clock signals but with a phase which is obtained by interpolation. The new clock signal is received at a feedback circuit 144. An output node 145 of the PI 120 is coupled to an output path 148 and to the inverter pair 149.

The PIs 120 and 140 can have a same configuration, in one approach.

The purpose of having two mixers is to generate differential clock phases (e.g., 0 and 180 degrees apart). Both phases are used in a half-rate receiver decision feedback equalizer, for example. The inverters 149 keep the differential clock edges 180 degree apart. With mismatches and circuit imperfections, the differential clock edges may have a delay skew in the two paths which are not exactly opposite to each other. The inverters will correct that and make the phases of ckp and ckn closer to 180 degrees apart.

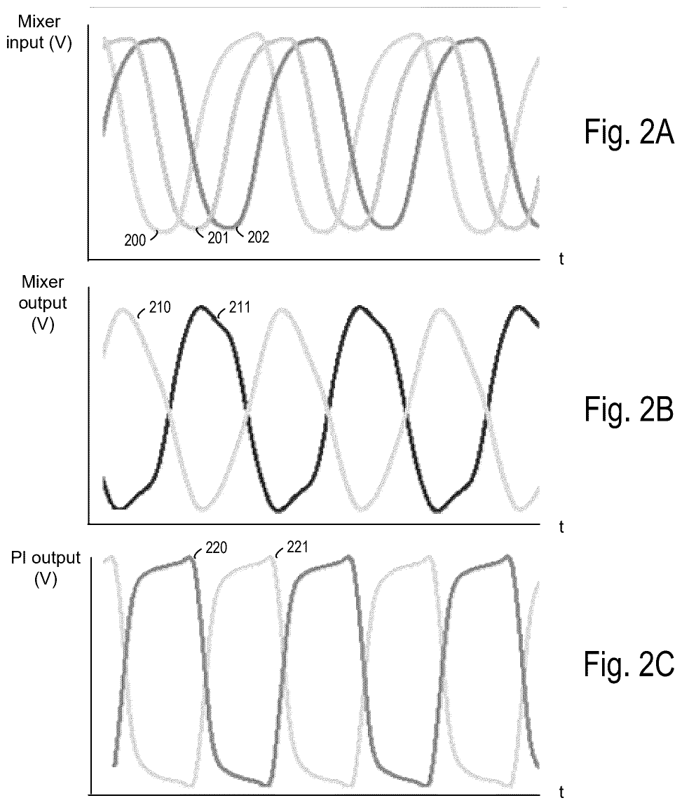

FIG. 2A depicts example plots 200, 201 and 202 of the clock signals clk[1], clk[2] and clk[3], respectively, which are input to the PI 120 of FIG. 1, in accordance with various embodiments. The vertical axis depicts the mixer input in volts (V) and the horizontal axis depicts time. The horizontal axes are time-aligned in FIGS. 2A-2C. The three clock signals can be 72 degrees apart in phase, for example. The plots represent the voltages at the input 121.

FIG. 2B depicts example plots 210 and 211 of clock signals output from the mixers 122 and 142, respectively, of FIG. 1, in accordance with various embodiments. The plots 210 and 211 represent the voltages at the output nodes 123 and 143, respectively.

FIG. 2C depicts example plots 220 and 221 of clock signals at the output nodes 125 and 145, respectively, of the feedback circuits 124 and 144, respectively, of FIG. 1, in accordance with various embodiments. The plots 220 and 221 represent the voltages at the output paths 128 and 148, respectively.

FIG. 3 depicts an example phase interpolator 300 which include a bias generator 327, and an example implementation of the mixer 122 and feedback circuit 124 of FIG. 1, in accordance with various embodiments. The mixer can include one or more legs for each clock signal. In this example, the mixer includes two legs for both clk[1] and clk[2] and one leg for clk[3] since clk[3] is input to both mixers 122 and 142 in FIG. 1. Each leg represents a current path. The legs have outputs which are combined at the input of the feedback circuit 124, at the output node 123. Each leg can have a same configuration, in one approach.

In an example implementation, the feedback circuit includes one or more stages of inverters 129 and a feedback path 127 with a variable resistor 126. Three inverters are shown as an example but one or more can be used. The inverters are an example of amplification stages.

For example, legs 310 and 311 receive clk[1], legs 320 and 321 receive clk[2] and leg 330 receives clk[3]. The three clock signals are received at the input 121 and distributed as clk[1], clk[2] and clk[3] on input paths 312, 313 and 314, respectively. Input path 312 is coupled to legs 310 and 311, input path 313 is coupled to legs 320 and 321 and input path 314 is coupled to leg 330.

The representative leg 310 includes, in series, a power supply node 316 at Vcc, first and second pMOS transistors T7 and T8, respectively, having control gates G7 and G8, respectively, an output node 340, first and second nMOS transistors T10 and T9, respectively, having control gates G10 and G9, respectively, and a ground node G, all of which form a current path 305. The output node 340 is coupled between the transistors T8 and T9, e.g., between the drains of the transistors T8 and T9. The output node 340 is a respective output node of the leg 310. Clk[1] is received at an input path 314 which is coupled at one side to a capacitor C1 and a following resistor R1 and at the other side to a capacitor C2 and a following resistor R2. R1 and R2 are coupled to paths 325 and 326 to receive biases Vpbias (a p-type transistor bias which can be common to the different legs) and Vnbias (an n-type transistor bias which can be common to the different legs), respectively, from a bias generator 327. These biases are used to provide voltages at the nodes 317 and 315 to drive G7 and G10, respectively. The voltages at the nodes 317 and 315 vary as the clock signal, e.g., clk[1], varies since G7 and G10 are biased as a function of an AC-coupled version of clk[1]. The voltage of clk[1] is coupled to G7 and G10 via C1 and C2, respectively.

The bias generator 327 is coupled to the control gate G7 of the first p-type transistor T7 via R1 and the path 325, and to the control gate G10 of the first n-type transistor T10 via R2 and the path 326. The bias generator 327 is coupled to C1 via R1 and to C2 via R2.

Specifically, the voltage at the node 317 is based on Vpbias, a voltage drop across R1, and an AC-coupled version of clk[1], and the voltage at the node 315 is based on Vnbias, a voltage drop across R2, and an AC-coupled version of clk[1].

Even if the legs associated with different clocks receive a common value of Vpbias and Vnbias, the control gate voltages for T7 and T10 can vary as the amplitude of the different clocks vary.

The capacitors C1 and C2 are to alternating-current (AC)-couple the different clock signals when the different clock signals are received at the inputs paths of the different legs of the mixer.

In one approach, the p-type and n-type transistors of the bias generator 327 are replicas of the p-type and n-type transistors, respectively, of the legs. This helps minimize PVT variations. Transistors which are replicas of one another can have the same proportions, within a tolerance, either to the same scale or different scales, for instance.

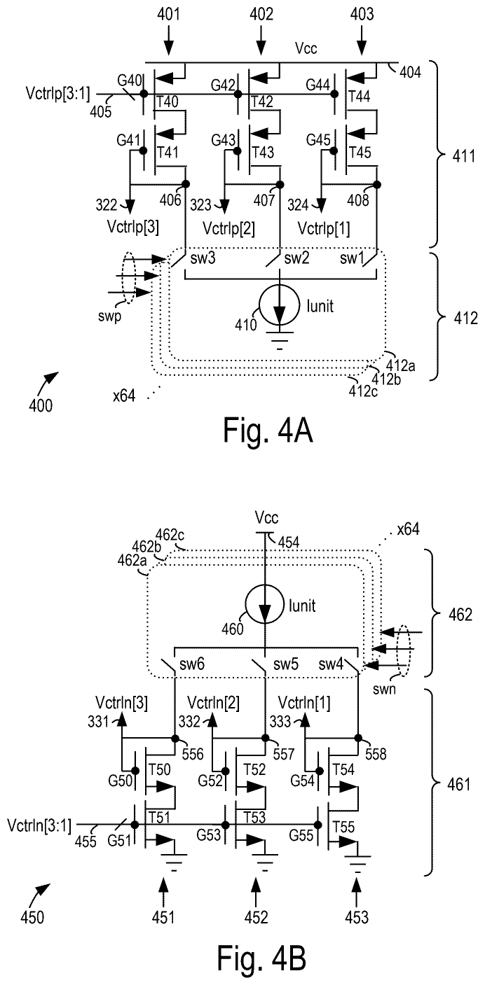

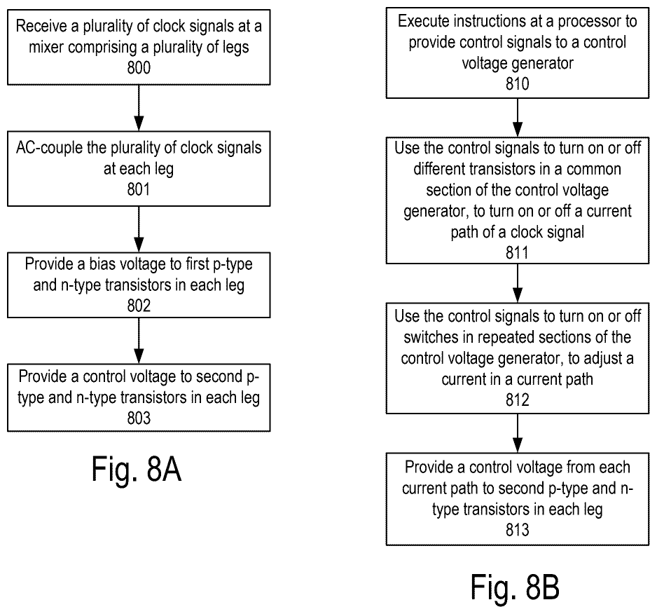

The first (pMOS) control voltage generator 400 is used to provide voltages to the gate G8 in each of the legs, and a second (nMOS) control voltage generator 450 is used to provide voltages to the gate G9 in each of the legs, in one approach. See FIGS. 4A and 4B for example implementations. The first and second control voltage generators 400 and 450, respectively, can receive respective first and second control signals Vctrlp[3:1] and Vctrln[3:1], respectively, which identify which legs to activate. In some cases, all legs are activated, e.g., when all input clocks are used by the PI, and in other cases, fewer than all legs are activated, e.g., when fewer than all input clocks are used by the PI. The first and second control signals can be provided, e.g., by a processor which is configured to execute instructions stored on a storage medium. For example, see the processor circuitry 952, the instructions 988, and/or the instructions 982 in the memory circuitry 954 in FIG. 8. The first and second control signals can further include control signals swp and swn to be used by the voltage generators 400 and 450, respectively, to control the switches in the voltage generators.

In particular, the first control voltage generator 400 provides a voltage Vctrlp[1] on a path 322 to the legs 310 and 311, a voltage Vctrlp[2] on a path 323 to the legs 320 and 321, and a voltage Vctrlp[3] on a path 324 to the leg 330. Similarly, the second control voltage generator 450 provides a voltage Vctrln[1] on a path 331 to the legs 310 and 311, a voltage Vctrln[2] on a path 332 to the legs 320 and 321, and a voltage Vctrlp[3] on a path 333 to the leg 330. Vctrlp[1], Vctrlp[2] and Vctrlp[3] are p-type control voltages (for p-type transistors in the legs such as T8) for legs which receive the different clock signals clk[1], clk[2] and clk[3], respectively. Vctrln[1], Vctrln[2] and Vctrln[3] are n-type control voltages (for n-type transistors in the legs such as T9) for legs which receive the different clock signals clk[1], clk[2] and clk[3], respectively.

The amount of current in each leg is controlled by the control voltages, the bias voltages and the clock signal. The output current from each leg is summed at the input 123 of the feedback circuit 124, which is also the mixer output node. The input 123 is coupled to the output nodes 340 and 341 of the clk[1] legs 310 and 311, respectively, the output nodes 350 and 351 of the clk[2] legs 320 and 321, respectively, and the output node 360 of the clk[3] legs 330.

The bias generator 327 includes first and second current paths 328 and 329, respectively. The first current path 328 includes, in series, a power supply node 334, pMOS transistors T1 and T2, a node 335, nMOS transistors T3 and T4, and a ground node. The second current path 329 includes, in series, the power supply node 334, pMOS transistors T5 and T6, and a current sink 336. T1 has a control gate G1 coupled to a node 337 which in turn is coupled to the path 325 to provide Vpbias, to a control gate G5 of T5, and to the current sink 336. T2 has a control gate G2 coupled to ground and to a control gate G6 of T6. The node 335 is coupled to the path 326 to provide Vnbias. T3 has a control gate G3 coupled to a power supply node 338 at Vcc. T4 has a control gate G4 coupled to a node 339 to receive Vnbias.

In one possible approach, a single bias generator is coupled to each of the legs in the PI 120 and in the PI 140. In another approach, separate bias generators are used for separate PIs.

The current in the leg 310, and therefore at the output node 340, is a function of the degree to which the transistors T7, T8, T9 and T10 are conductive or turned on by their respective control gate voltages. For the pMOS transistors T7 and T8, a lower voltage results in greater current while for the nMOS transistors T9 and T10, a higher voltage results in greater current.

In one approach, the PI includes a plurality of legs, wherein different legs of the plurality of legs are configured to receive different clock signals which have different phases, and each leg comprises a current path to generate a current at a respective output node, the current paths comprise, in series, first p-type transistors, second p-type transistors biased by different p-type control voltages corresponding to the different clock signals, first n-type transistors, and second n-type transistors biased by different n-type control voltages corresponding to the different clock signals; a bias generator coupled to the first p-type transistors and the first n-type transistors to provide the common p-type bias and the common n-type bias, respectively; and one or more control voltage generators coupled to second p-type and second n-type transistors to provide the different p-type control voltages and the different n-type control voltages, respectively.

In summary, the mixer 122 has two (or other multiple number) of modified CMOS-inverter-based legs or unit cells with AC-coupled inputs, with separate bias voltages provided for the pMOS and nMOS transistors T7 and T10, respectively. The weights of the input clocks are set by the control voltages Vctrlp and Vctrln and the numbers of unit cells enabled if multiple units are connected to the same input.

The bias generator 327 is a circuit that provides the bias voltages of the PI. The bias voltages can be adjusted for different operational speed and PVT corners. By using a constant current and a replica of the mixer with a diode-connected structure, the bias generator 327 can effectively tune the mixer strength over PVT variations.

Following the mixer is a multi-stage inverter with shunt resistor feedback. The feedback resistor 126 reduces the DC impedance at the mixer output 123 and biases the circuit at high gain for the operating frequency. Unlike a CMOS-inverter-based PI which requires a high input voltage swing, the PI 300 can work with a low-to-medium input voltage swing and provide a rail-to-rail voltage at the output 125, which usually would require additional CML-to-CMOS converters in the path.

The mixer control voltages are generated by current DACs (in the voltage generators 400 and 450) with a diode-connected load, where the load is a replica of the mixer nMOS/pMOS structure. By applying a DAC, a high resolution of the PI is achieved without impacting the bandwidth of the mixer.

Additionally, the PI can be implemented with a slight modification to accommodate three input clock phases in PCIe. In this case, the proposed PI is instantiated four times to generate the in-phase (I) clock and quadrature phase (Q) output with a differential output.

FIG. 4A depicts an example implementation of the first control voltage generator 400 of FIG. 3, in accordance with various embodiments. The first control voltage generator 400 includes a common section 411 and a plurality of repeated sections 412 coupled to the common section. In this example, there are 64 instances of the repeated section. A larger number of instances of the repeated section provides the ability to control the voltages Vctrlp[1], Vctrlp[2], and Vctrlp[3] with a smaller step size, in a finer-grained approach. This results in the ability to control the phase of the clock which is output from the mixer with a smaller step size and therefore with more accuracy. Example repeated sections 412a, 412b, 412c, . . . are depicted.

The first control voltage generator 400 includes three current paths-one for each of the clock signals received by the mixer. The magnitude of the current in each current path can be adjusted based on the number of repeated sections which are coupled to the current path by the respective switches. For example, a current path 401 for clk[1] includes, in the common section, a power supply node 404, pMOS transistors T40 and T41 having gates G40 and G41, respectively, and in each instance of the repeated section, a switch sw3, a current sink 410 and a ground. G40 is coupled to a multi-signal path 405 which receives the control signals Vctrlp[3:1]. T41 is a diode-connected transistor having its gate G41 connected to its drain 406 and to the path 322 to provide Vctrlp[3] to the leg 330 of the mixer 122. T41, T43 and T45 are different diode-connected p-type transistors which are coupled to control gates of p-type transistors of different current paths in a mixer which correspond to different clock signals.

Similarly, a current path 402 for clk[2] includes, in the common section, the power supply node 404, pMOS transistors T42 and T43 having gates G42 and G43, respectively, and in each instance of the repeated section, a switch sw2, the current sink 410 and ground. G42 is coupled to the multi-signal path 405. T43 is a diode-connected transistor having its gate G43 connected to its drain 407 and to the path 323 to provide Vctrlp[2] to the legs 320 and 321.

A current path 403 for clk[3] includes, in the common section, the power supply node 404, pMOS transistors T44 and T45 having gates G44 and G45, respectively, and in each instance of the repeated section, a switch sw1, the current sink 410 and ground. G44 is coupled to the multi-signal path 405. T45 is a diode-connected transistor having its gate G45 connected to its drain 408 and to the path 324 to provide Vctrlp[1] to the legs 310 and 311.

Vctrlp[3:1] can include three separate control signals-first, second and third control signals to turn on (make conductive) or off (make non-conductive) T40, T42 and T44, respectively. This provides the option to turn some current paths off if the associated clock signal is not being use for phase interpolation. The control signals can also adjust the current strength during the on state of the transistors. The strength of the current depends on how much current from the current sink 410 is switched into the specific path.

As mentioned, controls signals swp can also be provided by a processor or other control circuit to control the switches in each of the repeated sections of the first control voltage generator 400. In one approach, the switches can be controlled individually in each repeated section to provide many steps in the PI. The current sink is configured to sink a current Iunit.

The repeated sections 412a, 412b, 412c . . . are current DACs which convert digital control signals to an output current.

In one approach, the diode-connected p-type transistors of the first control voltage generator 400 (e.g., T41, T43, and T45) are replicas of the p-type transistors of the current path of the legs (e.g., T7 and T8). The diode-connected p-type transistors provide a load in the first control voltage generator 400 which is a replica of the load in the leg. This helps minimize PVT variations.

FIG. 4B depicts an example implementation of the second control voltage generator 450 of FIG. 3, in accordance with various embodiments. The second control voltage generator 450 includes a common section 461 and a plurality of repeated sections 462 coupled to the common section. In this example, there are 64 instances of the repeated section. A larger number of instances of the repeated section provides the ability to control the voltages Vctrin [1], Vctrln[2], and Vctrln[3] with a smaller step size. This results in the ability to control the phase of the clock which is output from the mixer with a smaller step size and therefore with more accuracy. Example repeated sections 462a, 462b, 462c, . . . are depicted.

The second control voltage generator 450 includes three current paths. The magnitude of the current in each current path can be adjusted based on the number of repeated sections which are coupled to the current path by the switches. A current path 451 for clk[1] includes, in each of the repeated sections, a power supply node 454, a current source 460, a switch sw6, and in the common section, nMOS transistors T50 and T51 having gates G50 and G51, respectively, and a ground. G51 is coupled to a multi-signal path 455 which receives the control signals Vctrln[3:1]. T50 is a diode-connected transistor having its gate G50 connected to its drain 556 and to the path 331 to provide Vctrln[3] to the leg 330. T50, T52 and T54 are different diode-connected n-type transistors which are coupled to control gates of n-type transistors of different current paths in a mixer which correspond to different clock signals.

Similarly, a current path 452 for clk[2] includes, in each of the repeated sections, the power supply node 454, the current source 460, a switch sw5, and in the common section, nMOS transistors T52 and T53 having gates G52 and G53, respectively, and ground. G53 is coupled to the multi-signal path 455. T52 is a diode-connected transistor having its gate G52 connected to its drain 557 and to the path 332 to provide Vctrln[2] to the legs 320 and 321.

A current path 453 for clk[1] includes, in each of the repeated sections, the power supply node 454, the current source 460, a switch sw4, and in the common section, nMOS transistors T54 and T55 having gates G54 and G55, respectively, and ground. G55 is coupled to the multi-signal path 455. T54 is a diode-connected transistor having its gate G54 connected to its drain 558 and to the path 333 to provide Vctrln[1] to the legs 310 and 311.

Vctrln[3:1] can include three separate signals-first, second and third control signals to turn on or off T51, T53 and T55, respectively. This provides the option to turn some current paths off if the associated clock signal is not being use for phase interpolation.

Controls signals swn can be provided by a processor to control the switches in each of the repeated sections of the second control voltage generator 450. In one approach, the switches can be controlled individually in each repeated section to provide many steps in the PI. The current source is configured to source a current lunit.

The repeated sections 462a, 462b, 462c . . . are current DACs.

In one approach, the diode-connected n-type transistors of the second control voltage generator 450 (e.g., T50, T52, and T54) are replicas of the n-type transistors of the current path of the legs (e.g., T9 and T10). The diode-connected n-type transistors provide a load in the second control voltage generator 450 which is a replica of the load in the leg. This helps minimize PVT variations.

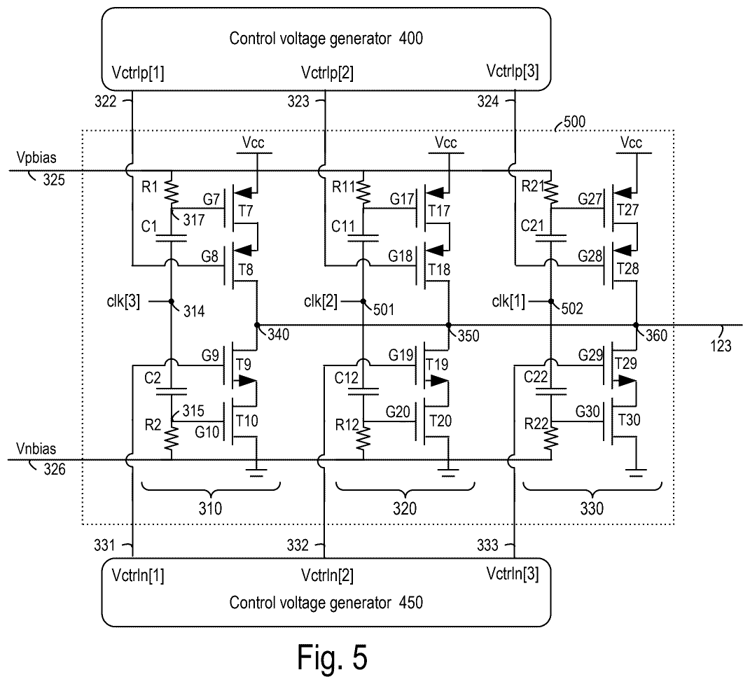

FIG. 5 depicts a circuit 500 which provides an example implementation of the mixer legs 310, 320 and 330 of FIG. 3 which receive clock signals clk[1], clk[2] and clk[3], respectively, in accordance with various embodiments. The mixer legs are depicted in an unfolded format so that legs which receive different clocks—one leg per clock—are visible. The configuration of the leg 310 was discussed in connection with FIG. 3. The legs 320 and 330 can have a same configuration, in one approach. As discussed, Vctrlp[1] and Vctrln[1] are used to drive G8 and G9.

The leg 320 includes, in series, a power supply node at Vcc, first and second pMOS transistors T17 and T18, respectively, having control gates G17 and G18, respectively, the output node 350, first and second nMOS transistors T20 and T19, respectively, having control gates G20 and G19, respectively, and a ground node. The output node 350 is coupled between the transistors T18 and T19. Clk[2] is received at a node 501 which is coupled at one side to a capacitor C11 and a following resistor R11 and at the other side to a capacitor C12 and a following resistor R12. R11 and R12 are coupled to the paths 325 and 326 to receive the biases Vpbias and Vnbias, respectively. These biases are used to provide voltages to drive G17 and G20. Also, Vctrlp[2] and Vctrln[2] are used to drive G18 and G19.

The leg 330 includes, in series, a power supply node at Vcc, first and second pMOS transistors T27 and T28, respectively, having control gates G27 and G28, respectively, the output node 360, first and second nMOS transistors T30 and T29, respectively, having control gates G30 and G29, respectively, and a ground node. The output node 360 is coupled between the transistors T18 and T19. Clk[1] is received at a node 502 which is coupled at one side to a capacitor C21 and a resistor R21 and at the other side to a capacitor C22 and a resistor R22. R21 and R22 are coupled to the paths 325 and 326 to receive the biases Vpbias and Vnbias, respectively. These biases are used to provide voltages to drive G27 and G30. Also, Vctrlp[1] and Vctrln[1] are used to drive G28 and G29.

In one approach, the resistors R1, R11 and R21 have the same resistance, and the resistors R2, R12 and R22 have the same resistance. In one approach, each of these resistors has the same resistance.

FIG. 6A depicts a phase diagram consistent with the phase interpolator 300 of FIG. 3, in accordance with various embodiments. In an example with five different clocks signals, the phases can be separated by 360/5-72 degrees, resulting in the phases P0, P72, P144, P216 and P288. As an example, an arrow 600 represents a phase shift of 108 degrees, from P0 to P108, and an arrow 601 represents a corresponding phase shift of 108 degrees, from P144 to P252. In one approach, the clock signals are provided according to PAM and include clock signals having in-phase (I) components and quadrature (Q) components.

FIG. 6B depicts a circuit 610 to provide in-phase (I) components of signals having phases consistent with FIG. 6A, in accordance with various embodiments. The circuit includes a mixer 611 which receives clock signals with phases of P0, P72 and P144, and a mixer 612 which receives clock signals with phases of P144, P216 and P288. The outputs of the mixers 611 and 612 are clock signals Ickp and Ickn, respectively. An inverter pair 613 is also coupled to the mixers 611 and 612.

FIG. 6C depicts a circuit 620 to provide quadrature (Q) components of signals having phases consistent with FIG. 6A, in accordance with various embodiments. The circuit includes a mixer 621 which receives clock signals with phases of P144, P216 and P288, and a mixer 622 which receives clock signals with phases of P288, P0 and P72. The outputs of the mixers 621 and 622 are clock signals Qckp and Qckn, respectively. An inverter pair 623 is also coupled to the mixers 621 and 622.

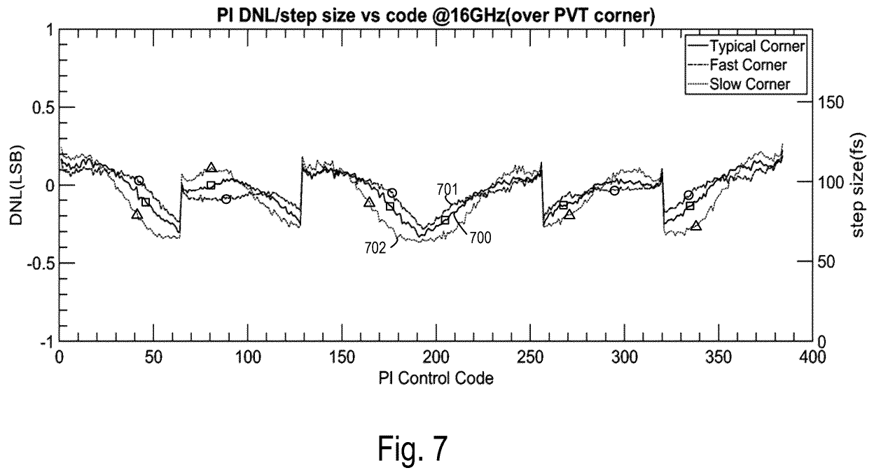

FIG. 7 depicts example plots of a differential nonlinearity (DNL) versus PI code for different process, voltage and temperature (PVT) corners consistent with the phase interpolator 300 of FIG. 3, in accordance with various embodiments. The vertical axes depict a least significant bit (LSB) of DNL and a step size, and the horizontal axis depicts a PI control code. Plot 700 (squares) is for a typical corner, plot 701 (circles) is for a fast corner and plot 702 (triangles) is for a slow corner. A PVT corner refers to a specific combination of process, voltage, and temperature conditions that characterize the operating environment of an integrated circuit (IC). The process refers to variations in the manufacturing processes that can affect the performance and behavior of individual transistors and other components on the semiconductor chip. These variations include factors such as transistor dimensions, doping levels, and oxide thickness. Process variations can lead to differences in transistor speed, power consumption, and other characteristics. Voltage refers to the operating voltage applied to the integrated circuit. Variations in voltage can affect the speed, power consumption, and reliability of the IC. Temperature refers to the operating temperature of the integrated circuit. Temperature variations can affect the speed, leakage current, and reliability of semiconductor devices.

The plots demonstrate that the DNL advantageous remains essentially the same at different PVT corners, confirming a high level of linearity for the PI described herein. The PI achieves a DNL of less than about 0.5 LSB, for example.

FIG. 8A depicts a flowchart of a method for operating a PI consistent with the circuits of FIGS. 1-5, in accordance with various embodiments. Operation 800 includes receiving a plurality of clock signals at a mixer comprising a plurality of legs. Operation 801 includes AC-coupling the plurality of clock signals at each leg, e.g., using the capacitors C1 and C2. Operation 802 includes providing a bias voltage to first p-type and n-type transistors in each leg, e.g., p-type transistor T7 and n-type transistor T10. Operation 803 includes providing a control voltage to second p-type and n-type transistors in each leg, e.g., p-type transistor T8 and n-type transistor T9.

FIG. 8B depicts a flowchart of a method consistent with operation 803 of FIG. 8A, in accordance with various embodiments. Operation 810 includes executing instructions at a processor to provide control signals to a control voltage generator. Operation 811 includes using the control signals, e.g., Vctrlp[3:1] and Vctrln[3:1], to turn on or off different transistors, e.g., T40, T42, T44, T51, T53 and T55, in a common section 411 or 461 of the control voltage generator (FIGS. 4A and 4B), to turn on or off a current path of a clock signal. Operation 812 includes using the control signals, e.g., swn and swp, to turn on or off switches, e.g., sw1, sw2 and sw3, in repeated sections 412 and 462 of the control voltage generator (FIGS. 4A and 4B), to adjust a current in a current path. Operation 813 includes providing a control voltage, e.g., Vctrlp[1], Vctrlp[2], Vctrlp[3], Vctrln[1], Vctrln[2] and Vctrln[3], from each current path to second p-type and n-type transistors in each leg. The magnitude of the current in each current path sets the control voltage.

One possible implementation includes an apparatus comprising means to perform the methods. Another possible implementation includes a machine-readable storage including machine-readable instructions which, when executed, cause a computer to implement the methods. Another possible implementation includes a computer program comprising instructions which, when executed by a computer, cause the computer to carry out the methods.

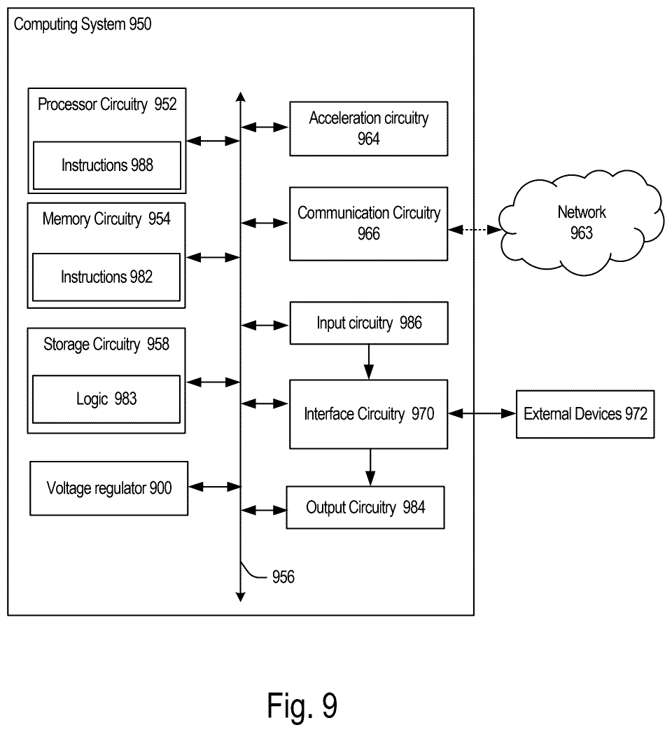

FIG. 9 illustrates an example of components that may be present in a computing system 950 for implementing the techniques (e.g., operations, processes, methods, and methodologies) described herein. The phase interpolators described herein including the PIs 120 and 140 of FIGS. 1-5 may be implemented in the communication circuitry 966, for example, or in any of the components of the computing system 950.

The computing system 950 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 950, or as components otherwise incorporated within a chassis of a larger system. In one approach, all or part of the computing system 950 is provided in a SoP, System in Package (SiP) or a System on Chip (SoC).

A voltage regulator 900 can provide a voltage Vout to one or more of the components of the computing system 950. The memory circuitry 954 may store instructions and the processor circuitry 952 may execute the instructions to perform the functions described herein.

The system 950 includes processor circuitry in the form of one or more processors 952. The processor circuitry 952 includes circuitry such as, but not limited to one or more processor cores and one or more of cache memory, low drop-out voltage regulators (LDOs), interrupt controllers, serial interfaces such as SPI, 12C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 952 may include one or more hardware accelerators (e.g., same or similar to acceleration circuitry 964), which may be microprocessors, programmable processing devices (e.g., FPGA, ASIC, etc.), or the like. The one or more accelerators may include, for example, computer vision and/or deep learning accelerators. In some implementations, the processor circuitry 952 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 952 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 952 may be coupled with or may include memory/storage and may be configured to execute instructions stored in the memory/storage to enable various applications or operating systems to run on the platform 950. The processors (or cores) 952 is configured to operate application software to provide a specific service to a user of the platform 950. In some embodiments, the processor(s) 952 may be a special-purpose processor(s)/controller(s) configured (or configurable) to operate according to the various embodiments herein.

As examples, the processor(s) 952 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP) TM processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 952 may be a part of a system on a chip (SoC), System-in-Package (SiP), a multi-chip package (MCP), and/or the like, in which the processor(s) 952 and other components are formed into a single integrated circuit, or a single package, such as the Edison™ or Galileo™ SoC boards from Intel® Corporation. Other examples of the processor(s) 952 are mentioned elsewhere in the present disclosure.

The system 950 may include or be coupled to acceleration circuitry 964, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 964 may comprise logic blocks or logic fabric and other interconnected resources that may be programmed (configured) to perform various functions, such as the procedures, methods, functions, etc. of the various embodiments discussed herein. In such implementations, the acceleration circuitry 964 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 952 and/or acceleration circuitry 964 may include hardware elements specifically tailored for machine learning and/or artificial intelligence (AI) functionality. In these implementations, the processor circuitry 952 and/or acceleration circuitry 964 may be, or may include, an AI engine chip that can run many different kinds of AI instruction sets once loaded with the appropriate weightings and training code. Additionally or alternatively, the processor circuitry 952 and/or acceleration circuitry 964 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 952 and/or acceleration circuitry 964 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 950 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 950 also includes system memory 954. Any number of memory devices may be used to provide for a given amount of system memory. As examples, the memory 954 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 954 may be, or include, non-volatile memory such as read-only memory (ROM), crasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 954 is controlled by a memory controller. The individual memory devices may be of any number of different package types such as single die package (SDP), dual die package (DDP) or quad dic package (Q17P). Any number of other memory implementations may be used, such as dual inline memory modules (DIMMs) of different varieties including but not limited to microDIMMs or MiniDIMMs.

Storage circuitry 958 provides persistent storage of information such as data, applications, operating systems and so forth. In an example, the storage 958 may be implemented via a solid-state disk drive (SSDD) and/or high-speed electrically crasable memory (commonly referred to as “flash memory”). Other devices that may be used for the storage 958 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 954 and/or storage circuitry 958 may also incorporate three-dimensional (3D) cross-point (XPOINT) memories from Intel® and Micron®.

The memory circuitry 954 and/or storage circuitry 958 is/are configured to store computational logic 983 in the form of software, firmware, microcode, or hardware-level instructions to implement the techniques described herein. The computational logic 983 may be employed to store working copies and/or permanent copies of programming instructions, or data to create the programming instructions, for the operation of various components of system 950 (e.g., drivers, libraries, application programming interfaces (APIs), etc.), an operating system of system 950, one or more applications, and/or for carrying out the embodiments discussed herein. The computational logic 983 may be stored or loaded into memory circuitry 954 as instructions 982, or data to create the instructions 982, which are then accessed for execution by the processor circuitry 952 to carry out the functions described herein. The processor circuitry 952 and/or the acceleration circuitry 964 accesses the memory circuitry 954 and/or the storage circuitry 958 over the interconnect (IX) 956. The instructions 982 direct the processor circuitry 952 to perform a specific sequence or flow of actions, for example, as described with respect to flowchart(s) and block diagram(s) of operations and functionality depicted previously. The various elements may be implemented by assembler instructions supported by processor circuitry 952 or high-level languages that may be compiled into instructions 988, or data to create the instructions 988, to be executed by the processor circuitry 952. The permanent copy of the programming instructions may be placed into persistent storage devices of storage circuitry 958 in the factory or in the field through, for example, a distribution medium (not shown), through a communication interface (e.g., from a distribution server (not shown)), over-the-air (OTA), or any combination thereof.

The IX 956 couples the processor 952 to communication circuitry 966 for communications with other devices, such as a remote server (not shown) and the like. The communication circuitry 966 is a hardware element, or collection of hardware elements, used to communicate over one or more networks 963 and/or with other devices. In one example, communication circuitry 966 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 966 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 956 also couples the processor 952 to interface circuitry 970 that is used to connect system 950 with one or more external devices 972. The external devices 972 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 950, which are referred to as input circuitry 986 and output circuitry 984. The input circuitry 986 and output circuitry 984 include one or more user interfaces designed to enable user interaction with the platform 950 and/or peripheral component interfaces designed to enable peripheral component interaction with the platform 950. Input circuitry 986 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 984 may be included to show information or otherwise convey information, such as sensor readings, actuator position(s), or other like information. Data and/or graphics may be displayed on one or more user interface components of the output circuitry 984. Output circuitry 984 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 950. The output circuitry 984 may also include speakers and/or other audio emitting devices, printer(s), and/or the like. Additionally or alternatively, sensor(s) may be used as the input circuitry 984 (e.g., an image capture device, motion capture device, or the like) and one or more actuators may be used as the output device circuitry 984 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 950 may communicate over the IX 956. The IX 956 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 956 may be a proprietary bus, for example, used in a SoC based system.

The number, capability, and/or capacity of the elements of system 950 may vary, depending on whether computing system 950 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 950 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a mixer comprising a plurality of legs, wherein different legs of the plurality of legs are coupled to different input paths for clock signals and to a common output node, wherein a leg of the plurality of legs comprises a current path having in series, a power supply node, p-type transistors, n-type transistors, a ground node, a respective output node coupled between the p-type and n-type transistors, first and second capacitors coupled to a respective input path of the different input paths, and first and second resistors coupled to the first and second capacitors, respectively; a bias generator coupled to the resistors; a first control voltage generator coupled to one of the p-type transistors; and a second control voltage generator coupled to one of the n-type transistors.

Example 2 includes the apparatus of Example 1, further comprising a feedback circuit coupled to the common output node, wherein the feedback circuit comprises one or more stages of inverters, and a resistor in a feedback path.

Example 3 includes the apparatus of Example 1 or 2, wherein in the leg, the p-type transistors comprises a first p-type transistor coupled to the power supply node and the one of the p-type transistors coupled between the first p-type transistor and the respective output node.

Example 4 includes the apparatus of any one of Examples 1-3, wherein: the first capacitor is coupled between the respective input path and the first resistor; and a control gate of the first p-type transistor is coupled to a node which is between the first capacitor and the first resistor.

Example 5 includes the apparatus of any one of Examples 1-4, wherein in the leg, the n-type transistors comprise a first n-type transistor coupled to the ground and the one of the n-type transistors coupled between the first n-type transistor and the respective output node.

Example 6 includes the apparatus of Example 5, wherein: the second capacitor is coupled between the respective input path and the second resistor; and a control gate of the first n-type transistor is coupled to a node which is between the second capacitor and the second resistor.

Example 7 includes the apparatus of any one of Examples 1-6, wherein: the first control voltage generator comprises a common section and a plurality of instances of a repeated section; and the repeated sections comprise different switches corresponding to the different clock signals, and a current sink.

Example 8 includes the apparatus of Example 7, wherein the common section comprises p-type transistors which are replicas of the p-type transistors of the current path of the leg.

Example 9 includes the apparatus of any one of Examples 1-8, wherein: the second control voltage generator comprises a common section and a plurality of instances of a repeated section; and the repeated sections comprise different switches corresponding to the different clock signals, and a current source.

Example 10 includes the apparatus of Example 9, wherein the common section comprises n-type transistors which are replicas of the n-type transistors of the current path of the leg.

Example 11 includes the apparatus of any one of Examples 1-10, wherein: the first control voltage generator is to provide different control voltages corresponding to the different clock signals to one of the p-type transistors in the plurality of legs; and the second control voltage generator is to provide different control voltages corresponding to the different clock signals to one of the n-type transistors in the plurality of legs.

Example 12 includes the apparatus of any one of Examples 1-11, wherein the bias generator comprises p-type transistors which are replicas of the p-type transistors of the leg and n-type transistors which are replicas of the n-type transistors of the leg.

Example 13 includes a phase interpolator, comprising: a plurality of legs, wherein: different legs of the plurality of legs are configured to receive different clock signals which have different phases; each leg comprises a current path to generate a current at a respective output node; the current paths comprise, in series, first p-type transistors, second p-type transistors biased by different p-type control voltages corresponding to the different clock signals, first n-type transistors, and second n-type transistors biased by different n-type control voltages corresponding to the different clock signals; and input paths coupled to the first p-type transistors and the first n-type transistors via first and second capacitors, respectively; a bias generator coupled to the first p-type transistors and the first n-type transistors via first and second resistors, respectively; and one or more control voltage generators coupled to the second p-type and second n-type transistors to provide the different p-type control voltages and the different n-type control voltages, respectively.

Example 14 includes the phase interpolator of Example 13, further comprising one or more amplification stages with a shunt resistor feedback circuit coupled to a common output node of the plurality of legs.

Example 15 includes the phase interpolator of Example 13 or 14, wherein: the one or more control voltage generators include a first control voltage generator coupled to the second p-type transistors and a second control voltage generator coupled to the second n-type transistors; the first control voltage generator comprises p-type transistors which are replicas of the second p-type transistors; and the second control voltage generator comprises n-type transistors which are replicas of the second n-type transistors.

Example 16 includes the phase interpolator of any one of Examples 13-15, wherein the first and second capacitors are to alternating-current (AC)-couple the different clock signals when the different clock signals are received at the inputs paths.

Example 17 includes a system, comprising: a memory to store instructions; and a processor to execute the instructions to provide control signals to a control voltage generator, wherein: the control voltage generator comprises a respective common section having different diode-connected p-type transistors corresponding to different clock signals and a plurality of instances of a repeated section coupled to the respective common section; the repeated sections each comprise different switches coupled to the different diode-connected p-type transistors, and a current sink; the control signals are to control the different switches in the repeated sections; and the different diode-connected p-type transistors are coupled to control gates of p-type transistors of different current paths in a mixer.

Example 18 includes the system of Example 17, wherein: the respective common section comprises different p-type transistors coupled to the different diode-connected p-type transistors; and the control signals are to turn on or off the different p-type transistors.

Example 19 includes the system of Example 17 or 18, wherein: the control voltage generator is a first control voltage generator and the system further comprises a second control voltage generator; the processor is to execute the instructions to provide control signals to the second control voltage generator; the second control voltage generator comprises a respective common section having different diode-connected n-type transistors corresponding to the different clock signals and a plurality of instances of a repeated section coupled to the respective common section; and in the second control voltage generator: the repeated sections each comprise different switches coupled to the different diode-connected n-type transistors, and a current source; the control signals are to control the different switches in the repeated sections; and the different diode-connected n-type transistors are coupled to control gates of n-type transistors of the different current paths in the mixer.

Example 20 includes the system of Example 19, wherein in the second control voltage generator: the respective common section comprises different n-type transistors coupled to the different diode-connected n-type transistors; and the control signals are to turn on or off the different n-type transistors.

Example 21 includes a method for operating a phase interpolator (PI), comprising: receiving a plurality of clock signals at a mixer comprising a plurality of legs; alternating-current (AC)-coupling the plurality of clock signals at each leg; providing a bias voltage to first p-type and n-type transistors in each leg; and providing a control voltage to second p-type and n-type transistors in each leg.

Example 22 includes an apparatus, comprising means to perform the method of Example 21.

Example 23 includes a machine-readable storage including machine-readable instructions which, when executed, cause a computer to implement the method of Example 21.

Example 24 includes a computer program comprising instructions which, when executed by a computer, cause the computer to carry out the method of Example 21.

Example 25 includes a method for providing a control voltage in a phase interpolator (PI), comprising: executing instructions at a processor to provide control signals to a control voltage generator; using the control signals to turn on or off different transistors in a common section of the control voltage generator, to turn on or off a current path of a clock signal; using the control signals to turn on or off switches in repeated sections of the control voltage generator to adjust a current in a current path; and providing a control voltage from each current path to second p-type and n-type transistors in each leg of a plurality of legs of the PI, wherein the magnitude of the current in each current path sets the control voltage.

Example 26 includes an apparatus, comprising means to perform the method of Example 25.

Example 27 includes a machine-readable storage including machine-readable instructions which, when executed, cause a computer to implement the method of Example 25.

Example 28 includes a computer program comprising instructions which, when executed by a computer, cause the computer to carry out the method of Example 25.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a mixer comprising a plurality of legs, wherein different legs of the plurality of legs are coupled to different input paths for clock signals and to a common output node, wherein a leg of the plurality of legs comprises a current path having in series, a power supply node, p-type transistors, n-type transistors, a ground node, a respective output node coupled between the p-type and n-type transistors, first and second capacitors coupled to a respective input path of the different input paths, and first and second resistors coupled to the first and second capacitors, respectively;
a bias generator coupled to the resistors;
a first control voltage generator coupled to one of the p-type transistors; and
a second control voltage generator coupled to one of the n-type transistors.

2. The apparatus of claim 1, further comprising a feedback circuit coupled to the common output node, wherein the feedback circuit comprises one or more stages of inverters, and a resistor in a feedback path.

3. The apparatus of claim 1, wherein in the leg, the p-type transistors comprises a first p-type transistor coupled to the power supply node and the one of the p-type transistors coupled between the first p-type transistor and the respective output node.

4. The apparatus of claim 3, wherein:
the first capacitor is coupled between the respective input path and the first resistor; and
a control gate of the first p-type transistor is coupled to a node which is between the first capacitor and the first resistor.

5. The apparatus of claim 1, wherein in the leg, the n-type transistors comprise a first n-type transistor coupled to the ground and the one of the n-type transistors coupled between the first n-type transistor and the respective output node.

6. The apparatus of claim 5, wherein:
the second capacitor is coupled between the respective input path and the second resistor; and
a control gate of the first n-type transistor is coupled to a node which is between the second capacitor and the second resistor.

7. The apparatus of claim 1, wherein:
the first control voltage generator comprises a common section and a plurality of instances of a repeated section; and
the repeated sections comprise different switches corresponding to the different clock signals, and a current sink.

8. The apparatus of claim 7, wherein the common section comprises p-type transistors which are replicas of the p-type transistors of the current path of the leg.

9. The apparatus of claim 1, wherein:
the second control voltage generator comprises a common section and a plurality of instances of a repeated section; and
the repeated sections comprise different switches corresponding to the different clock signals, and a current source.

10. The apparatus of claim 9, wherein the common section comprises n-type transistors which are replicas of the n-type transistors of the current path of the leg.

11. The apparatus of claim 1, wherein:
the first control voltage generator is to provide different control voltages corresponding to the different clock signals to one of the p-type transistors in the plurality of legs; and
the second control voltage generator is to provide different control voltages corresponding to the different clock signals to one of the n-type transistors in the plurality of legs.

12. The apparatus of claim 1, wherein the bias generator comprises p-type transistors which are replicas of the p-type transistors of the leg and n-type transistors which are replicas of the n-type transistors of the leg.

13. A phase interpolator, comprising:
a plurality of legs, wherein:
different legs of the plurality of legs are configured to receive different clock signals which have different phases;
each leg comprises a current path to generate a current at a respective output node;
the current paths comprise, in series, first p-type transistors, second p-type transistors biased by different p-type control voltages corresponding to the different clock signals, first n-type transistors, and second n-type transistors biased by different n-type control voltages corresponding to the different clock signals; and
input paths coupled to the first p-type transistors and the first n-type transistors via first and second capacitors, respectively;
a bias generator coupled to the first p-type transistors and the first n-type transistors via first and second resistors, respectively; and
one or more control voltage generators coupled to the second p-type and second n-type transistors to provide the different p-type control voltages and the different n-type control voltages, respectively.

14. The phase interpolator of claim 13, further comprising one or more amplification stages with a shunt resistor feedback circuit coupled to a common output node of the plurality of legs.

15. The phase interpolator of claim 13, wherein:
the one or more control voltage generators include a first control voltage generator coupled to the second p-type transistors and a second control voltage generator coupled to the second n-type transistors;
the first control voltage generator comprises p-type transistors which are replicas of the second p-type transistors; and
the second control voltage generator comprises n-type transistors which are replicas of the second n-type transistors.

16. The phase interpolator of claim 13, wherein the first and second capacitors are to alternating-current (AC)-couple the different clock signals when the different clock signals are received at the inputs paths.

17. A system, comprising:
a memory to store instructions; and
a processor to execute the instructions to provide control signals to a control voltage generator, wherein:
the control voltage generator comprises a respective common section having different diode-connected p-type transistors corresponding to different clock signals and a plurality of instances of a repeated section coupled to the respective common section;
the repeated sections each comprise different switches coupled to the different diode-connected p-type transistors, and a current sink;
the control signals are to control the different switches in the repeated sections; and
the different diode-connected p-type transistors are coupled to control gates of p-type transistors of different current paths in a mixer.

18. The system of claim 17, wherein:
the respective common section comprises different p-type transistors coupled to the different diode-connected p-type transistors; and
the control signals are to turn on or off the different p-type transistors.

19. The system of claim 17, wherein:
the control voltage generator is a first control voltage generator and the system further comprises a second control voltage generator;
the processor is to execute the instructions to provide control signals to the second control voltage generator;
the second control voltage generator comprises a respective common section having different diode-connected n-type transistors corresponding to the different clock signals and a plurality of instances of a repeated section coupled to the respective common section; and
in the second control voltage generator:
the repeated sections each comprise different switches coupled to the different diode-connected n-type transistors, and a current source;
the control signals are to control the different switches in the repeated sections; and
the different diode-connected n-type transistors are coupled to control gates of n-type transistors of the different current paths in the mixer.

20. The system of claim 19, wherein in the second control voltage generator:
the respective common section comprises different n-type transistors coupled to the different diode-connected n-type transistors; and
the control signals are to turn on or off the different n-type transistors
